(19) United States
(12) Patent Application Publication
(10) Pub. No.: US 2014/0353614 A1
(43) Pub. Date: Dec. 4, 2014

(54) ORGANIC LIGHT EMITTING DISPLAY DEVICE AND METHOD OF MANUFACTURING THE SAME

(71) Applicant: Samsung Display Co., Ltd., Yongin-city (KR)

(72) Inventor: Sang-Il PARK, Yongin-city (KR)

(73) Assignee: Samsung Display Co., Ltd., Yongin-city (KR)

(21) Appl. No.: 14/069,806

(22) Filed: Nov. 1, 2013

(30) Foreign Application Priority Data
May 29, 2013 (KR) 10-2013-0060766

(51) Int. Cl. H01L 27/32; H01L 51/56

(52) U.S. Cl. CPC H01L 27/3225; H01L 51/56
USPC 257/40; 438/23

(57) ABSTRACT

Provided is an organic light emitting display device. The organic light emitting display device includes: a substrate including a display region and a plurality of peripheral regions adjacent the display region; a display structure disposed in the display region; and a strain gauge disposed in two peripheral regions facing each other among the plurality of peripheral regions.

### CROSS-REFERENCE TO RELATED APPLICATION(S)

This application claims priority from and the benefit of Korean Patent Application No. 10-2013-0060766, filed on May 29, 2013, which is hereby incorporated by reference for all purposes as if fully set forth herein.

### BACKGROUND

1. Field

Exemplary embodiments of the present disclosure relate generally to an electronic device. More particularly, exemplary embodiments of the present disclosure relate to an organic light emitting display device in which a display panel and a strain gauge are integrated, and a method of manufacturing the organic light emitting display device.

2. Discussion of the Background

An organic light emitting display device is widely used because the organic light emitting display device has many desirable characteristics such as low power consumption, slim and compact size, etc. If the display panel of an organic light emitting display device can be bent (i.e., the display panel includes a flexible substrate or film made of bendable materials), the display panel may avoid severe damage by external impact that the device may be subject to.

Generally, the organic light emitting display device includes a strain gauge structure attached to the peripheral region (i.e., outer boundaries) of the display panel. Thus, based on the strain gauge structure, the organic light emitting display device may detect the bend amount and/or the bending direction of the organic light emitting display device.

However, when the organic light emitting display device includes a strain gauge structure attached to the peripheral region (i.e., outer boundaries) of the display panel, the manufacturing cost of the organic light emitting display device is likely increased. In addition, the strain gauge structure in the outer boundaries will increase the overall thickness of the device, thereby significantly limiting the range of bending for the organic light emitting display device.

### SUMMARY

Exemplary embodiments of the present disclosure provide an organic light emitting display device in which a display panel and a strain gauge are integrated.

Example embodiments of the present disclosure provide a method of manufacturing the organic light emitting display device.

According to one exemplary embodiment, an organic light emitting display device may include: a substrate comprising a display region and a plurality of peripheral regions adjacent the display region; a display structure disposed in the display region of the substrate; and a strain gauge disposed in two peripheral regions facing each other among the plurality of peripheral regions.

In one exemplary embodiment, the display structure may include a first gate electrode disposed on the substrate; a first gate insulating layer disposed on the first gate electrode; a first active layer disposed on the first gate insulating layer; a first insulating interlayer overlying the first gate insulating layer and the first active layer; a first source electrode connected to the first active layer; a first drain electrode connected to the first active layer, and the display structure and the strain gauge structure are formed directly on the same layer.

In one exemplary embodiment, the strain gauge structure may include a second gate electrode disposed on the substrate; a second gate insulating layer disposed on the second gate electrode; a second active layer disposed on the second gate insulating layer; a second insulating interlayer overlying the second gate insulating layer and the second active layer; a second source electrode connected to the second active layer; a second drain electrode connected to the second active layer, and the plurality of peripheral regions surround the display region.

In one exemplary embodiment, the second active layer may be configured to be electrically controllable based on a voltage that is applied to at least one of the second gate electrode, the second source electrode, and the second drain electrode.

In one exemplary embodiment, the second active layer may include a semiconductor oxide, the semiconductor oxide comprising at least one of indium (In), zinc (Zn), gallium (Ga), tin (Sn), titanium (Ti), aluminum (Al), hafnium (Hf), zirconium (Zr), and magnesium (Mg).

In one exemplary embodiment, the strain gauge structure may include at least one first metal pattern disposed on the substrate; a third active layer disposed on the first metal pattern; and a second metal pattern disposed on the third active layer, and the strain gauge structure and the display structure are formed directly on the same layer.

In one exemplary embodiment, the second metal pattern may include an interdigitated structure.

In one exemplary embodiment, the third active layer may be configured to be electrically controllable based on a voltage that is applied to at least one of the first metal pattern and the second metal pattern.

In accordance with one exemplary embodiment, an organic light emitting display device may include: a substrate comprising a display region and a peripheral region adjacent the display region, the peripheral region having a plurality of peripheral regions; a display structure disposed on the display region of the substrate; and a strain gauge structure disposed on the entire plurality of peripheral regions.

In one exemplary embodiment, the display structure may include a first gate electrode disposed on the substrate; a first gate insulating layer disposed on the first gate electrode; a first active layer disposed on the first gate insulating layer; a first insulating interlayer overlying the first gate insulating layer and the first active layer; a first source electrode connected to the first active layer; a first drain electrode connected to the first active layer, and the display structure and the strain gauge structure are formed directly on the same layer.

In one exemplary embodiment, the strain gauge structure may include a second gate electrode disposed on the substrate; a second gate insulating layer disposed on the second gate electrode; a second active layer disposed on the second gate insulating layer; a second insulating interlayer overlying the second gate insulating layer and the second active layer; a second source electrode connected to the second active layer; a second drain electrode connected to the second active layer, and the strain gauge structure and the display structure are formed directly on the same layer.

In one exemplary embodiment, the second active layer may be electrically controlled based on a voltage that is applied to at least one of the second gate electrode, the second source electrode, and the second drain electrode.

In one exemplary embodiment, the second active layer may include a semiconductor oxide, the semiconductor oxide comprising at least one of indium, zinc, gallium, tin, titanium, aluminum, hafnium, zirconium, and magnesium.

In one exemplary embodiment, the strain gauge structure may include at least one first metal pattern disposed on the substrate; a third active layer disposed on the at least one first metal pattern; a second metal pattern disposed on the third active layer, and the strain gauge structure and the display structure are formed directly on the same layer.

In one exemplary embodiment, the second metal pattern may include an interdigitated structure.

In one exemplary embodiment, the third active layer may be configured to be electrically controllable based on a voltage that is applied to at least one of the first metal pattern and the second metal pattern.

In accordance with one exemplary embodiment, a method of manufacturing an organic light emitting display device includes: providing a substrate comprising a display region and a plurality of peripheral regions adjacent the display region; forming a display structure in the display region of the substrate; and forming a strain gauge in two peripheral regions facing each other among the plurality of peripheral regions.

In one exemplary embodiment, the display structure and the strain gauge structure may be formed on the same layer of the substrate.

In accordance with one exemplary embodiment, a method of manufacturing an organic light emitting display device includes: providing a substrate comprising a display region and a plurality of peripheral regions adjacent the display region; forming a display structure in the display region of the substrate; and forming a strain gauge in the entire plurality of peripheral regions.

In one exemplary embodiment, the display structure and the strain gauge structure may be formed directly on the same layer.

Therefore, an organic light emitting display device according to one exemplary embodiment may have a simplified structure in which a display panel and a strain gauge are integrated (i.e., the display panel and the strain gauge are formed on the same layer). In addition, the manufacturing cost of the organic light emitting display device may be reduced, and the manufacturing process of the organic light emitting display device may be simplified.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a perspective view illustrating an organic light emitting display device in accordance with one exemplary embodiment.

FIG. 2 is a perspective view illustrating an organic light emitting display device in accordance with one exemplary embodiment.

FIG. 3 is a cross-sectional view illustrating an example of a strain gauge structure included in organic light emitting display devices of FIGS. 1 and 2.

FIG. 4 is a cross-sectional view illustrating another example of a strain gauge structure included in organic light emitting display devices of FIGS. 1 and 2.

FIG. 5 is a cross-sectional view illustrating still another example of a strain gauge structure included in organic light emitting display devices of FIGS. 1 and 2.

FIG. 6 is a cross-sectional view taken along a line A-A′ of FIG. 1 and a line B-B′ of FIG. 2.

FIGS. 7 through 10 are diagrams illustrating a method of manufacturing an organic light emitting display device.

FIGS. 11 through 13 are diagrams illustrating a method of manufacturing an organic light emitting display device.

### DETAILED DESCRIPTION OF THE EMBODIMENTS

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “on” versus “directly on,” “between” versus “directly between,” “adjacent” versus “directly adjacent,” etc.). It will be understood that for the purposes of this disclosure, “at least one of X, Y, and Z” can be construed as X only, Y only, Z only, or any combination of two or more items X, Y, and Z (e.g., XYZ, XYY, YZ, ZZ).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a perspective view illustrating an organic light emitting display device in accordance with one exemplary embodiment.

Referring to FIG. 1, an organic light emitting display device 100 may include a substrate 110, a display structure 120, and a strain gauge structure 130.

The substrate 110 may include a display region I and a peripheral region II. The peripheral region II may surround the display region I. In accordance with one exemplary embodiment, the substrate 110 may include a flexible substrate. Alternatively, the substrate 110 may include a glass substrate, a quartz substrate, a transparent plastic substrate, a transparent resin substrate, etc. Examples of the transparent resin substrate include polyimide-based resin, acryl-based resin, polyacrylate-based resin, polyethyleneterephthalate-based resin, polycarbonate-based resin, sulfonic acid-based resin, polyether-based resin, etc.

A buffer layer (not shown) may be disposed on the substrate 110. In accordance with one exemplary embodiment, the buffer layer may prevent diffusion of metal atoms and/or impurities from the substrate 110. In the case that the substrate 110 may have a relatively irregular surface, the buffer layer may improve flatness of the surface of the substrate 110.

The buffer layer may be formed using a silicon compound. For example, the buffer layer may include silicon oxide (SiOx), silicon nitride (SiNx), silicon oxynitride (SiOxNy), silicon oxycarbide (SiOxCy), silicon carbon nitride (SiCxNy), etc. These may be used alone or in a mixture thereof.

In accordance with one exemplary embodiment, the display structure 120 may be disposed on the display region I. A configuration of the display structure 120 will be described below in detail. A peripheral circuit unit and the strain gauge structure 130 may be disposed on the peripheral region II.

The strain gauge structure 130 may be disposed on two peripheral regions facing each other among the plurality of peripheral regions. Accordingly, the strain gauge structure 130 may detect a strain generated when the shape of the organic light emitting display device 100 is changed. In accordance with one exemplary embodiment, when the organic light emitting display device 100 is substantially bent, rolled, or curved in a predetermined direction, a control signal that controls optical characteristics (e.g., the color coordinates of the organic light emitting display device 100, the luminance of the organic light emitting display device 100) may be inputted to the organic light emitting display device 100.

In accordance with one exemplary embodiment, when the organic light emitting display device 100 is bent, rolled, or curved in an axial direction, the strain gauge structure 130 disposed on two peripheral regions facing each other among the plurality of peripheral regions may detect the strain generated from the changed shape of the organic light emitting display device 100 and may generate an electric signal corresponding to the strain.

In accordance with one exemplary embodiment, the display structure 120 and the strain gauge structure 130 may be formed on the same layer of the substrate 110. That is, the strain gauge structure 130 may be formed on the substrate 110 during substantially the same process where the display structure 120 is formed on the substrate 110. Accordingly, the organic light emitting display device 100 may advantageously have a simplified structure. In addition, the manufacturing cost of the organic light emitting display device 100 may be reduced, and the manufacturing process of the organic light emitting display device 100 may be simplified.

In accordance with one exemplary embodiment, the strain gauge structure 130 may be formed on the substrate 110. The strain gauge structure 130 may include a second gate electrode, a second gate insulating layer, a second active layer, a second insulating interlayer, a second source electrode, and a second drain electrode. Alternatively, the strain gauge structure 130 may include at least one first metal pattern, a third active layer, and a second metal pattern. A configuration of the strain gauge structure 130 is described below in more detail.

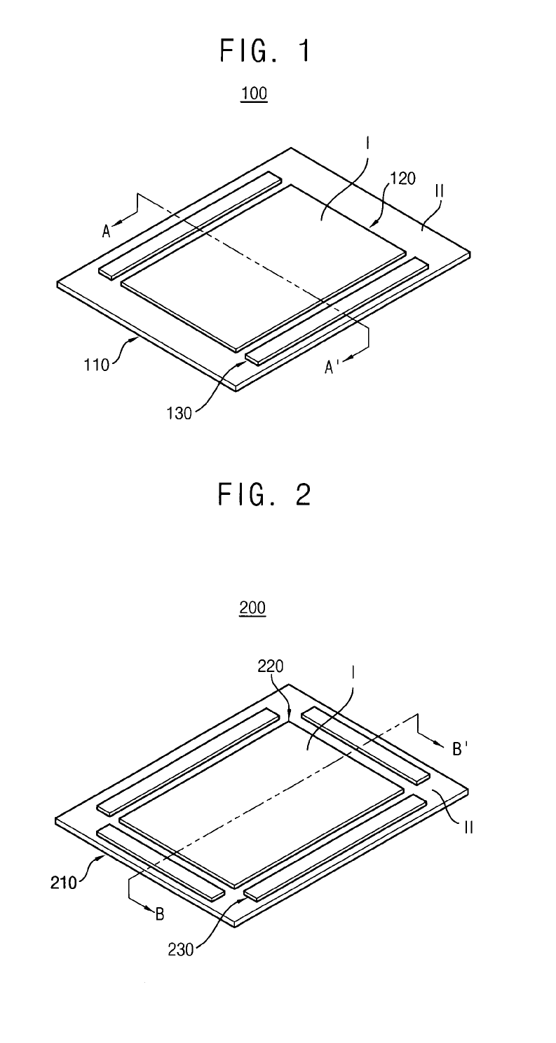

FIG. 2 is a perspective view illustrating an organic light emitting display device in accordance with one exemplary embodiment.

Referring to FIG. 2, the organic light emitting display device 200 may include a substrate 210, a display structure 220, a strain gauge structure 230, etc. Since the organic light emitting display device 200 of FIG. 2 has a structure that is substantially the same as or substantially similar to the organic light emitting display device 100 of FIG. 1 except for a strain gauge structure 230, the same descriptions will not be repeated below.

The display structure 120 may be disposed on a display region I, and the strain gauge structure 230 may be disposed on a peripheral region II.

In accordance with one exemplary embodiment, when the organic light emitting display device 200 is bent or curved in biaxial directions, the strain gauge structure 230 disposed on the entire plurality of peripheral regions may detect the strain generated from the change of the shape of the organic light emitting display device 200 and may generate an electric signal corresponding to the strain. In one exemplary embodiment, the strain gauge structure 230 may be disposed adjacent to at least one of the upper side, the lower side, the right side, and the left side of the display region I. However, these embodiments are exemplary, and the subject matter of the present disclosure is not limited thereto.

Therefore, the display structure 120 and the strain gauge structure 230 may be formed on the same layer of the substrate 210. That is, the strain gauge structure 230 may be formed on the substrate 210 while or in the same process where the display structure 220 is formed on the substrate 210. Accordingly, the organic light emitting display device 200 may have a simplified structure. In addition, the manufacturing cost of the organic light emitting display device 200 may be reduced, and the manufacturing process of the organic light emitting display device 200 may be simplified.

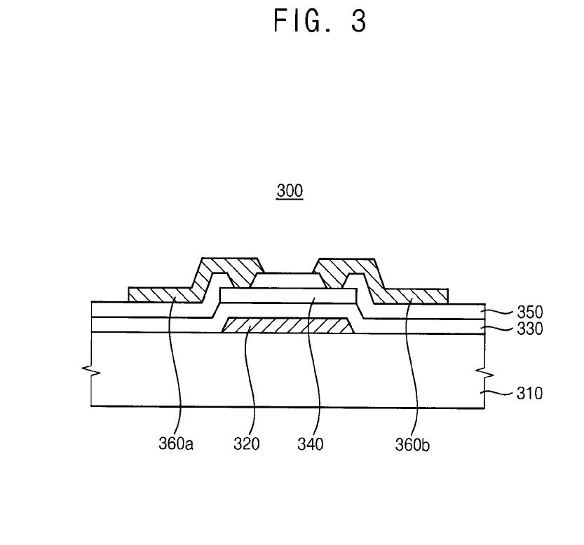

FIG. 3 is a cross-sectional view illustrating an example of a strain gauge structure included in organic light emitting display devices of FIGS. 1 and 2.

Referring to FIG. 3, a strain gauge structure 300 may be provided on a substrate 310. In accordance with one exemplary embodiment, the strain gauge structure 300 may include a second gate electrode 320, a second gate insulating layer 330, a second active layer 340, a second insulating interlayer 350, a second source electrode 360a, a second drain electrode 360b, etc. Although the strain gauge structure 300 may be described with reference to FIG. 3 to be substantially the same as or substantially similar to the strain gauge structures described above with reference to FIGS. 1 and 2, however, it will be appreciated by those of ordinary skill in the art that the strain gauge structure 300 illustrated in FIG. 3 may be formed in other strain gauge structures having various configurations that are suitable to achieve strain gauging, for instance, in one where the second gate electrode, the second gate insulating layer, the second active layer, the second insulating interlayer, the second source electrode, the second drain electrode, etc. may be disposed in various forms.

The substrate 310 may include a flexible substrate. Alternatively, the substrate 310 may include a glass substrate, a quartz substrate, a transparent plastic substrate, a transparent resin substrate, etc. Examples of the transparent resin substrate include polyimide-based resin, acryl-based resin, polyacrylate-based resin, polyethyleneterephthalate-based resin, polycarbonate-based resin, sulfonic acid-based resin, polyether-based resin, etc.

In accordance with one exemplary embodiment, a display structure and the strain gauge structure 300 may be formed on the same layer of the substrate 310. That is, the strain gauge structure 300 may be formed on the substrate 310 while or in the same process where a display structure is formed on the substrate 310. Accordingly, the organic light emitting display device can have a simplified structure. In addition, the manufacturing cost of the organic light emitting display device may be reduced, and the manufacturing process of the organic light emitting display device may be simplified.

In accordance with one exemplary embodiment, a buffer layer may be disposed on the substrate 310. In accordance with one exemplary embodiment, the buffer layer may prevent the diffusion of metal atoms and/or impurities from the substrate 310. In the case that the substrate 310 may have a relatively irregular surface, the buffer layer may improve flatness of the surface of the substrate 310.

The buffer layer may be formed using a silicon compound. For example, the buffer layer may include silicon oxide, silicon nitride, silicon oxynitride, silicon oxycarbide, silicon carbon nitride, etc. These may be used alone or in a mixture thereof.

The second gate electrode 320 may be disposed on the substrate 310. In accordance with one exemplary embodiment, the second gate electrode 320 may include metal, alloy, metal nitride, a transparent conductive material, etc. For example, the second gate electrode 320 may be formed using aluminum (Al), alloy containing aluminum, aluminum nitride (AlNx), silver (Ag), alloy containing silver, tungsten (W), tungsten nitride (WNx), copper (Cu), alloy containing copper, nickel (Ni), alloy containing nickel, chrome (Cr), chrome nitride (CrNx), molybdenum (Mo), alloy containing molybdenum, titanium (Ti), titanium nitride (TiNx), platinum (Pt), tantalum (Ta), tantalum nitride (TaNx), neodymium (Nd), scandium (Sc), zinc oxide (ZnOx), indium tin oxide (ITO), tin oxide (SnOx), indium oxide (InOx), gallium oxide (GaOx), indium zinc oxide (IZO), etc. These may be used alone or in a combination thereof.

Referring now to FIG. 3, a first gate electrode (not shown), a gate line (not shown), and the second gate electrode 320 may be formed on the same layer and may be made of the same material with one another.

In accordance with one exemplary embodiment, a first conductive layer may be formed on the substrate 310. Thereafter, the first conductive layer may be partially etched by a photolithography process or an etching process using an additional etching mask. Hence, the second gate electrode 320 may be provided on the substrate 310. In accordance with one exemplary embodiment, the second gate electrode 320 may have a single layer structure or a multi-layer structure, which may include a conductive material, a heat resistance material and/or a transparent conductive material.

The second gate insulating layer 330 may be formed on the substrate 310 to cover the second gate electrode 320.

In accordance with one exemplary embodiment, the second gate insulating layer 330 may include silicon oxide, metal oxide, etc. For example, the second gate insulating layer 330 may include aluminum oxide (AlOx), tantalum oxide (TaOx), hafnium oxide (HfOx), zirconium oxide (ZrOx), titanium oxide (TiOx), etc. These may be used alone or in a combination thereof.

Referring now to FIG. 3, a gate first insulating layer and the second gate insulating layer 330 may be formed on the same layer and may be made of the same material. In accordance with one exemplary embodiment, the first gate insulating layer and the second gate insulating layer 330 may have a single layer structure or a multi-layer structure, which may include silicon compounds and/or metal oxides.

The second active layer 340 may be formed on the second gate insulating layer 330. In accordance with one exemplary embodiment, the second active layer 340 may be positioned on a portion of the second gate insulating layer 330 under which the second gate electrode 320 is located.

In accordance with one exemplary embodiment, the second active layer 340 may include a binary compound containing indium (In), zinc (Zn), gallium (Ga), tin (Sn), titanium (Ti), aluminum (Al), halfnium (Hf), zirconium (Zr), magnesium (Mg), etc, a ternary compound, e.g., including such elements, a quaternary compound e.g., including such elements, etc. For example, the second active layer 340 may include indium-gallium-zinc oxide (IGZO), gallium zinc oxide (GaZnxOy), indium tin oxide (ITO), indium zinc oxide (IZO), zinc magnesium oxide (ZnMgxOy), zinc tin oxide (ZnSnxOy), zinc zirconium oxide (ZnZrxOy), zinc oxide (ZnOx), gallium oxide (GaOx), titanium oxide (TiOx), tin oxide (SnOx), indium oxide (SnOx), indium-gallium-hafnium oxide (IGHO), tin-aluminum-zinc oxide (TAZO), indium-gallium-tin oxide (IGSO), etc. These may be used alone or in a combination thereof. In one exemplary embodiment, the second active layer 340 may include a semiconductor oxide doped with lithium (Li), sodium (Na), manganese (Mn), nickel (Ni), palladium (Pd), copper (Cu), carbon (C), nitrogen (N), phosphorus (P), titanium, zirconium, vanadium (V), rubidium (Ru), germanium (Ge), tin, fluorine (F), etc. These may be used alone or in a mixture thereof.

Referring now to FIG. 3, a first active layer and the second active layer 340 may be formed on the same layer and may be made of the same material.

In accordance with one exemplary embodiment, a semiconductor oxide layer may be formed on the first gate insulating layer (not shown) and the second gate insulating layer 330. Thereafter, the semiconductor oxide layer may be partially etched by a photolithography process or an etching process using an additional etching mask. Hence, the second active layer 340 may be provided on the second gate insulating layer 330.

In accordance with one exemplary embodiment, the second active layer 340 may be electrically controlled based on a voltage that is applied to at least one of the second gate electrode 320, the second source electrode 360a, and the second drain electrode 360b. In this case, the organic light emitting display device may use the change of a resistance on the second active layer 340. Accordingly, the organic light emitting display device may detect a strain on the organic light emitting display device by using the change of a resistance on the second active layer 340.

The first insulating interlayer 350 may be formed on the second gate insulating layer 330 and the second active layer 340 to cover the second gate insulating layer 330 and the second active layer 340.

In accordance with one exemplary embodiment, the second insulating interlayer 350 may include silicon oxide, metal oxide, etc. For example, the second insulating interlayer 350 may include silicon oxide, silicon nitride, silicon oxynitride, silicon oxycarbide, silicon carbonnitride, aluminum oxide, tantalum oxide, hafnium oxide, zirconium oxide, titanium oxide, etc. These may be used alone or in a combination thereof.

Referring to FIG. 3, a first insulating interlayer and the second insulating interlayer 350 may be formed on the same layer and may be made of the same material. In accordance with one exemplary embodiment, the second insulating interlayer 350 may have a single layer structure or a multi-layer structure, which may include silicon compounds and/or metal oxides.

The second source electrode 360a and the second drain electrode 360b may be formed on the second insulating interlayer 350. In accordance with one exemplary embodiment, the second source electrode 360a and the second drain electrode 360b may include metal, alloy, metal nitride, a transparent conductive material, etc. For example, the second source electrode 360a and the second drain electrode 360b may be obtained using aluminum, alloy containing aluminum, aluminum nitride, silver, alloy containing silver, tungsten, tungsten nitride, copper, alloy containing copper, nickel, chrome, chrome nitride, molybdenum, alloy containing molybdenum, titanium, titanium nitride, zinc oxide, indium tin oxide, tin oxide, indium oxide, gallium oxide, indium zinc oxide, etc. These may be used alone or in a combination thereof.

Referring to FIG. 3, a first source electrode (not shown), a first drain electrode (not shown), the second source electrode 360a, and the second drain electrode 360b may be formed on the same layer and may be made of the same material. In accordance with one exemplary embodiment, a second conductive layer may be formed on the substrate 310. Thereafter, the second conductive layer may be partially etched by a photolithography process or an etching process using an additional etching mask. Hence, the second source electrode 360a, and the second drain electrode 360b may be provided on the second insulating interlayer 350. The second source electrode 360a and the second drain electrode 360b may include metal, alloy, conductive metal oxide, a transparent conductive material, etc. In accordance with one exemplary embodiment, the second source electrode 360a and the second drain electrode 360b may have a single layer structure or a multi-layer structure, which may include a conductive material, a heat resistance material and/or a transparent conductive material.

The second source electrode 360a and the second drain electrode 360b may be formed through the second insulating interlayer 350, and may contact the second active layer 340, respectively. The second source electrode 360a and the second drain electrode 360b may be separated from each other by a predetermined distance. Accordingly, each of the second source electrode 360a and the second drain electrode 360b may be symmetrically disposed on the second insulating interlayer 350, centering the underlying the second gate electrode 320.

With reference to FIG. 3, 360a is designated for the second source electrode, while 360b is designated for the second drain electrode. However, the subject matter of the present application is not limited thereto. For example, depending upon the voltages applied, 360b and 360a may denote the second source electrode and the second drain electrode, respectively.

Further, the strain gauge structure 300 according to one exemplary embodiment may include the second active layer 340. In this case, the second active layer 340 may be electrically controlled based on the voltage that is applied to at least one of the second gate electrode 320, the second source electrode 360a, and the second drain electrode 360b. Accordingly, the strain gauge structure 300 according to one exemplary embodiment may detect an initial resistance on the second active layer 340 and also a resistance on the second active layer 340 after the shape of the organic light emitting display device is changed. As a result, the strain gauge structure 300 according to one exemplary embodiment may detect the strain generated from the change of the shape of the organic light emitting display device by using the difference between the initial resistance of the second active layer 340 and the resistance of the second active layer 340 after the change of the shape of the organic light emitting display device.

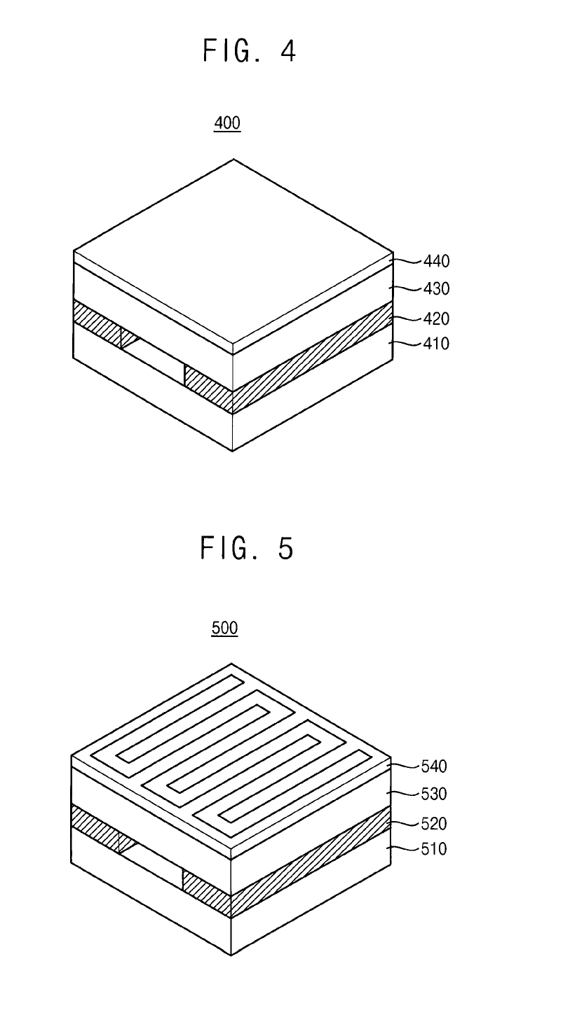

FIG. 4 is a cross-sectional view illustrating one example of a strain gauge structure included in organic light emitting display devices of FIGS. 1 and 2.

Referring to FIG. 4, a strain gauge structure 400 may be provided on a substrate 410. In accordance with one exemplary embodiment, the strain gauge structure 400 may include at least one first metal pattern 420, a second active layer 430, a second metal pattern 440, etc. However, it will be appreciated by those of ordinary skill in the art that the strain gauge structure 400 illustrated in FIG. 4 may be provided in other strain gauge structures having various configurations where the first metal pattern, the second active layer, the second metal pattern, etc. may be disposed in various forms.

The substrate 410 may include a flexible substrate. Alternatively, the substrate 410 may include a glass substrate, a quartz substrate, a transparent plastic substrate, a transparent resin substrate, etc. Since the substrate 410 of FIG. 4 has a structure that is substantially the same as or substantially similar to the substrate 310 of FIG. 3, the same descriptions will not be repeated.

The first metal pattern 420 may be disposed on the substrate 410. In accordance with one exemplary embodiment, the first metal pattern 420 may include metal, alloy, metal nitride, a transparent conductive material, etc. For example, the first metal pattern 420 may be formed using aluminum, alloy containing aluminum, aluminum nitride, silver, alloy containing silver, tungsten, tungsten nitride, copper, alloy containing copper, nickel, chrome, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, etc. These may be used alone or in a combination thereof.

Referring to FIG. 4, a first gate electrode, a gate line, and the first metal pattern 420 may be formed on the same layer and may be made of the same material.

In accordance with one exemplary embodiment, a first metal layer may be formed on the substrate 410. Thereafter, the first metal layer may be partially etched by a photolithography process or an etching process using an additional etching mask. Hence, the first metal pattern 420 may be provided on the substrate 410. The first metal pattern 420 may include metal, alloy, conductive metal oxide, a transparent conductive material, etc. In accordance with one exemplary embodiment, the first metal pattern 420 may have a single layer structure or a multi-layer structure, which may include a conductive material, a heat resistance material and/or a transparent conductive material. Multiple pieces constituting the first metal pattern 420 may be separated from each other by a predetermined distance. However, the subject matter of the present disclosure is not limited thereto.

The second active layer 430 may be disposed on the first metal pattern 420. In accordance with one exemplary embodiment, the second active layer 430 may include a binary compound containing indium, zinc, gallium, titanium, aluminum, halfnium, zirconium, magnesium, etc, a ternary compound, e.g., including such elements, and a quaternary compound, e.g., including such elements, etc. For example, the second active layer 430 may include may include indium-gallium-zinc oxide, gallium zinc oxide, indium tin oxide, indium zinc oxide, zinc magnesium oxide, zinc tin oxide, zinc zirconium oxide, zinc oxide, gallium oxide, titanium oxide, tin oxide, indium oxide, indium-gallium-hafnium oxide, tin-aluminum-zinc oxide, indium-gallium-tin oxide, etc. These may be used alone or in a combination thereof. In one exemplary embodiment, the second active layer 430 may include, instead of or in addition to the above-listed compounds, a semiconductor oxide doped with lithium, sodium, manganese, nickel, palladium, copper, carbon, nitrogen, phosphorus, titanium, zirconium, vanadium, rubidium, germanium, tin, fluorine, etc. These may be used alone or in a mixture thereof.

Referring to FIG. 4, a first active layer and the second active layer 430 may be formed on the same layer and may be made of the same material.

In accordance with one exemplary embodiment, a semiconductor oxide layer may be formed on the first metal pattern 420. Thereafter, the semiconductor oxide layer may be partially etched by a photolithography process or an etching process using an additional etching mask. Hence, the second active layer 430 may be provided on the first metal pattern 420.

The second metal pattern 440 may be disposed on the second active layer 430. In accordance with one exemplary embodiment, the second metal pattern 440 may include metal, alloy, metal nitride, a transparent conductive material, etc. For example, the second metal pattern 440 may be formed using aluminum, alloy containing aluminum, aluminum nitride, silver, alloy containing silver, tungsten, tungsten nitride, copper, alloy containing copper, nickel, chrome, chrome nitride, molybdenum, alloy containing molybdenum, titanium, titanium nitride, platinum, tantalum, tantalum nitride, neodymium, scandium, zinc oxide, indium tin oxide, tin oxide, indium oxide, gallium oxide, indium zinc oxide, etc. These may be used alone or in a combination thereof.

Referring to FIG. 4, a first source electrode, a first drain electrode, and the second metal pattern 440 may be formed on the same layer and may be made of the same material.

In accordance with one exemplary embodiment, a second metal layer may be formed on the second active layer 430. Thereafter, the second metal layer may be partially etched by a photolithography process or an etching process using an additional etching mask. Hence, the second metal pattern 440 may be provided on the second active layer 430. In accordance with one exemplary embodiment, the second metal pattern 440 may have a single layer structure or a multi-layer structure, which may include a conductive material, a heat resistance material and/or a transparent conductive material.

Therefore, the strain gauge structure 400 according to one exemplary embodiment may include the second active layer 430. In this case, the second active layer 430 may be electrically controlled based on the voltage that is applied to at least one of the first metal pattern 420 and the second metal pattern 440. Accordingly, the strain gauge structure 400 according to one exemplary embodiment may detect an initial resistance of the second active layer 430 and also a resistance of the second active layer 430 after the change of the shape of the organic light emitting display device. As a result, the strain gauge structure 400 according to one exemplary embodiment may detect the strain generated from the change of the shape of the organic light emitting display device by using the difference between the initial resistance of the second active layer 430 and the resistance of the second active layer 430 after the change of the shape of the organic light emitting display device.

FIG. 5 is a cross-sectional view illustrating one example of a strain gauge structure included in organic light emitting display devices of FIGS. 1 and 2.

Referring to FIG. 5, a strain gauge structure 500 may be provided on a substrate 510. In accordance with one exemplary embodiment, the strain gauge structure 500 may include at least one first metal pattern 520, a second active layer 530, a second metal pattern 540, etc. Since the strain gauge structure 500 of FIG. 5 has a structure that is substantially the same as or substantially similar to the strain gauge structure 400 of FIG. 4 except for a second metal pattern 540, the same descriptions will not be repeated.

The substrate 510 may include a flexible substrate. Alternatively, the substrate 510 may include a glass substrate, a quartz substrate, a transparent plastic substrate, a transparent resin substrate, etc.

Referring to FIG. 5, a first gate electrode, a gate line, a second gate electrode, and the first metal pattern 520 may be formed on the same layer and may be made of the same material.

The second active layer 530 may be disposed on the first metal pattern 520. In accordance with one exemplary embodiment, the second active layer 530 may include a binary compound containing indium, zinc, gallium, titanium, aluminum, halfnium, zirconium, magnesium, etc, a ternary compound, e.g., including such elements, and a quaternary compound, e.g., including such elements, etc. For example, the second active layer 530 may include indium-gallium-zinc oxide, gallium zinc oxide, indium tin oxide, indium zinc oxide, zinc magnesium oxide, zinc tin oxide, zinc zirconium oxide, zinc oxide, gallium oxide, titanium oxide, tin oxide, indium oxide, indium-gallium-hafnium oxide, tin-aluminum-zinc oxide, indium-gallium-tin oxide, etc. These may be used alone or in a combination thereof. In one exemplary embodiment, the second active layer 530 may include, instead of or in addition to the above-listed compounds, a semiconductor oxide doped with lithium, sodium, manganese, nickel, palladium, copper, carbon, nitrogen, phosphorus, titanium, zirconium, vanadium, rubidium, germanium, tin, fluorine, etc. These may be used alone or in a mixture thereof.

Referring to FIG. 5, a first active layer and the second active layer 530 may be formed on the same layer and may be made of the same material.

The second metal pattern 540 may be disposed on the second active layer 530. In accordance with one exemplary embodiment, the second metal pattern 540 may be patterned to have an interdigitated structure. The second metal pattern 540 may include metal, alloy, metal nitride, a transparent conductive material, etc. These may be used alone or in a combination thereof.

Referring to FIG. 5, a first source electrode and a first drain electrode may be formed on the same layer and may be made of the same material with the second metal pattern 540.

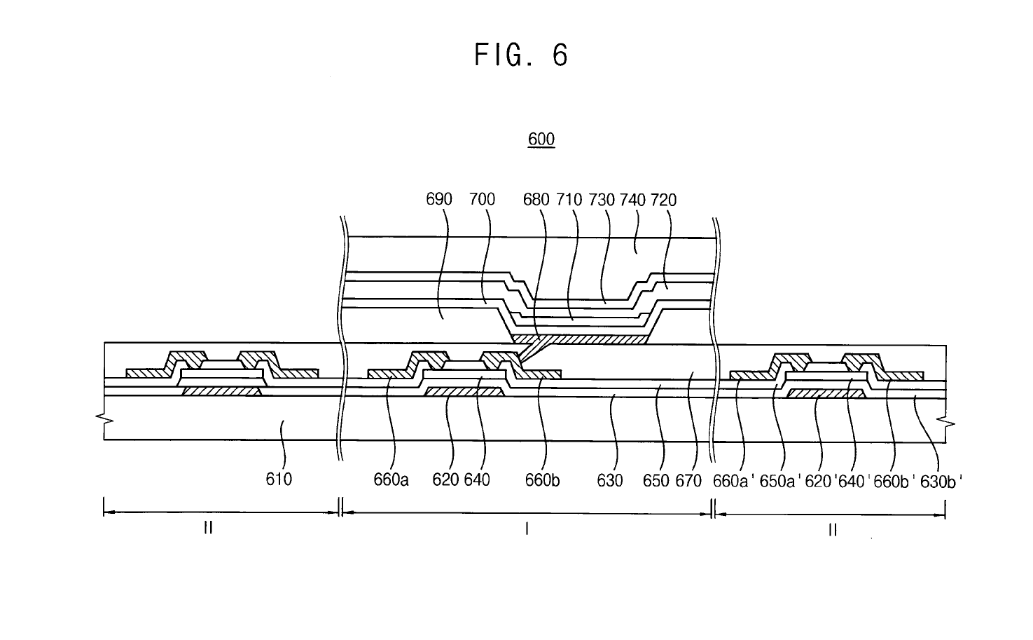

FIG. 6 is a cross-sectional view taken along a line A-A′ of FIG. 1 and a line B-B′ of FIG. 2.

Referring to FIG. 6, a display structure may be disposed in a display region I, and a strain gauge structure may be disposed in a peripheral region II. In accordance with one exemplary embodiment, the display region I may correspond to a light emission region, and the peripheral region II may correspond to a strain gauge region. The display structure may include a switching structure disposed on a substrate 610, a first electrode 680, a light emitting structure, a second electrode 730, etc. For example, an organic light emitting display device 600 in FIG. 6 may be a bottom emission type.

The switching structure may be disposed on the substrate 610. The first electrode 680 may be disposed on the switching structure and may be electrically connected to the switching structure. The light emitting structure may be disposed between the first electrode 680 and the second electrode 730.

When the organic light emitting display device 600 is an active matrix type, the switching structure may include a thin film transistor. In accordance with one exemplary embodiment, when the switching structure includes a thin film transistor, the switching structure may include a switching device, a plurality of insulating layers, etc.

As described above, when the switching device includes a thin film transistor, the switching device may include a first gate electrode 620, a first gate insulating layer 630, a first active layer 640, a first insulating interlayer 650, a first source electrode 660a, a first drain electrode 660b, etc.

The first gate electrode 620 may receive a gate signal, and the first source electrode 660a may receive a data signal. In accordance with one exemplary embodiment, the first drain electrode 660b may be electrically connected to the first electrode 680, and the first active layer 640 may make contact with the first source electrode 660a and the first drain electrode 660b.

In the organic light emitting display device described with reference to FIG. 6, the switching device including the thin film transistor may have a top gate structure in which the first gate electrode 620 may be disposed on the first active layer 640. However, the configuration of the switching device may not be limited thereto. For example, the switching device may have a bottom gate structure in which the first gate electrode 620 may be disposed under the first active layer 640.

Referring to FIG. 6, the light emitting structure may include a hole transfer layer 700, an organic light emitting layer 710, an electron transfer layer 720, etc. The organic light emitting layer 710 may include organic materials or a mixture of organic materials and inorganic materials for generating a red color of light, a green color of light and/or a blue color of light. Alternatively, the organic light emitting layer 710 may have a stacked structure that includes a plurality of light emitting films for generating a red color of light, a green color of light and a blue color of light to thereby provide a white color of light.

The first electrode 680 may be disposed between the switching structure and the light emitting structure. The second electrode 730 may be disposed between the light emitting structure and the upper substrate 740. A pixel defining layer 690 may be disposed in a region between the switching structure and the light emitting structure where the first electrode 680 is not positioned.

In accordance with one exemplary embodiment, the first electrode 680 may serve as an anode for providing holes into the hole transfer layer 700 of the light emitting structure, and the second electrode 730 may serve as a cathode for supplying electrons into the electron transfer layer 720. Depending on the emission type of the organic light emitting display device 600, the first electrode 680 may be a transparent electrode or a semi-transparent electrode, and the second electrode 730 may be a reflective electrode. For example, the first electrode 680 may include a transparent conductive material such as indium tin oxide, zinc tin oxide, indium zinc oxide, zinc oxide, tin oxide, gallium oxide, etc. The second electrode 730 may include a reflective material such as aluminum, platinum, silver, gold, chrome, tungsten, molybdenum, titanium, alloys thereof, nitrides thereof, etc. These may be used alone or in a combination thereof.

The upper substrate 740 may be disposed on the second electrode 730. The upper substrate 740 may include a transparent substrate such as a glass substrate, a quartz substrate, a transparent resin substrate, etc. Alternatively, the upper substrate 740 may include a flexible material. The upper substrate 740 may substantially oppose the substrate 610. In accordance with one exemplary embodiment, the substrate 610 and the upper substrate 740 may include substantially the same materials or different materials.

The strain gauge structure may include a second gate electrode 620′, a second gate insulating layer 630′, a second active layer 640′, a second insulating interlayer 650′, a second source electrode 660a′, a second drain electrode 660b′, etc. Although the strain gauge structure of FIG. 6 has a structure that is substantially the same as or substantially similar to the strain gauge structure of FIG. 3, it should understood that the strain gauge structures of FIGS. 4 and 5 may be employed to replace the strain gauge structure of FIG. 6. Since the strain gauge structure of FIG. 6 has a structure that is substantially the same as or substantially similar to the strain gauge structure of FIG. 3, the same descriptions will not be repeated.

In accordance with one exemplary embodiment, the strain gauge structure and the display structure 120 may be formed on the same layer. That is, the strain gauge structure may be formed on the substrate 610 while or in the same process where the display structure 120 is formed on the substrate 610. Accordingly, the organic light emitting display device 600 may have a simplified structure. In addition, the manufacturing cost of the organic light emitting display device 600 may be reduced, and the manufacturing process of the organic light emitting display device 600 may be simplified.

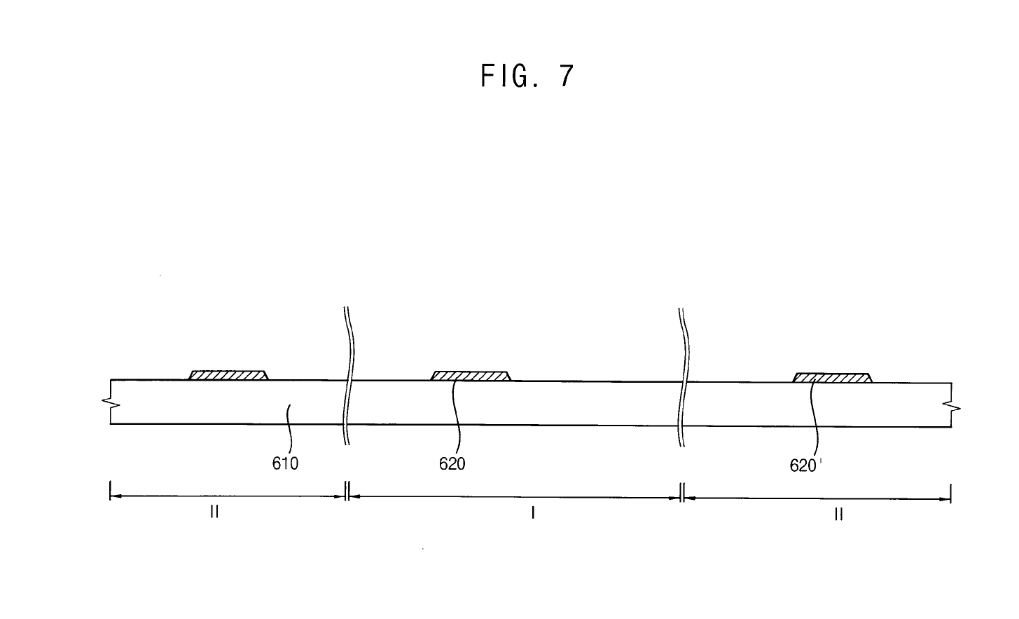

FIGS. 7 through 10 are diagrams illustrating a method of manufacturing an organic light emitting display device.

Referring to FIG. 7, a first gate electrode 620 and a second gate electrode 620′ may be formed on a substrate 610. In accordance with one exemplary embodiment, a first conductive layer may be formed on the substrate 610. Thereafter, the first conductive layer may be partially etched by a photolithography process or an etching process using an additional etching mask. Hence, the first gate electrode 620 and the second gate electrode 620′ may be provided on the substrate 610. The first conductive layer may be formed by a sputtering process, a chemical vapor deposition (CVD) process, an atomic layer deposition (ALD) process, a vacuum evaporation process, a printing process, etc. The first gate electrode 620 and the second gate electrode 620′ may include a conductive material, a heat resistance material, and/or a transparent conductive material. These may be used alone or in a combination thereof.

A buffer layer may be disposed on the substrate 610. In accordance with one exemplary embodiment, the buffer layer may prevent the diffusion of metal atoms and/or impurities from the substrate 610. The buffer layer may have a single layer structure or a multi-layer, which may include silicon oxide, silicon oxynitride, silicon nitride, etc. In the case that the substrate 610 may have a relatively irregular surface, the buffer layer may improve flatness of the surface of the substrate 610. In addition, when the buffer layer is on the substrate 610, the first gate electrode 620 and the second gate electrode 620′ may be easily formed, as the stress generated during the formation of the first gate electrode 620 and the second gate electrode 620′ may be decreased by the buffer layer.

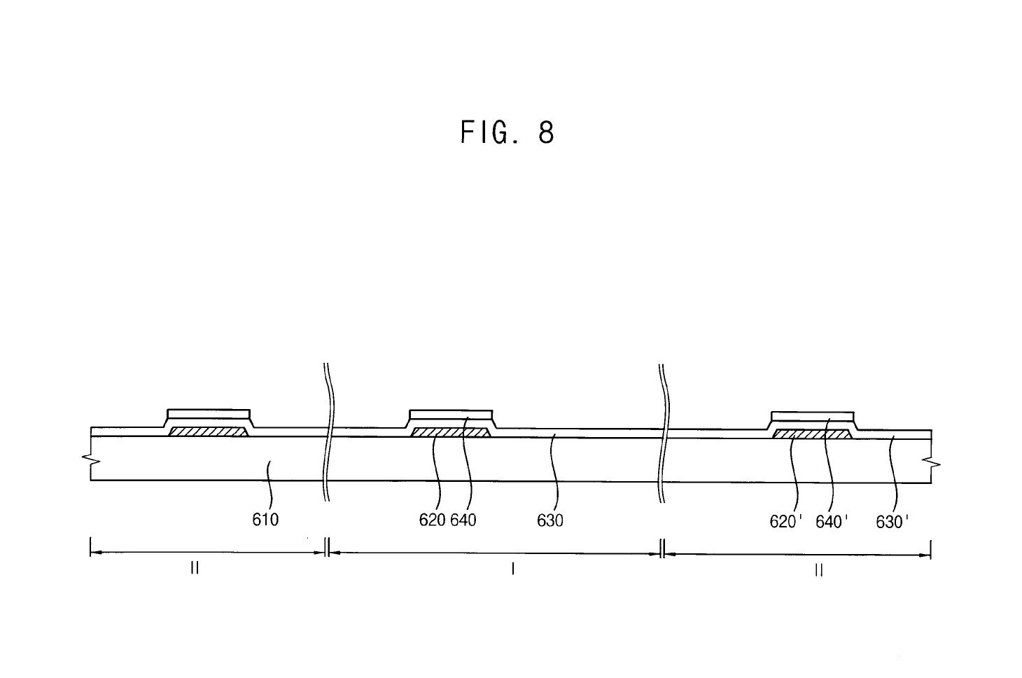

Referring to FIG. 8, a first gate insulating layer 630 and a second gate insulating layer 630′ may be formed on the first gate electrode 620 and the second gate electrode 620′. The first gate insulating layer 630 and the second gate insulating layer 630′ may be formed by a CVD process, a thermal oxidation process, a plasma enhanced chemical vapor deposition (PECVD) process, a high density plasma-chemical vapor deposition (HDP-CVD) process, etc. The first gate insulating layer 630 and the second gate insulating layer 630′ may include silicon oxide, metal oxide, etc. For example, the first gate insulating layer 630 and the second gate insulating layer 630′ may include silicon oxide, silicon oxynitride, hafnium oxide, zirconium oxide, aluminum oxide, tantalum oxide, etc. These may be used alone or in a combination thereof.

Referring to FIG. 8, a first active layer 640 and a second active layer 640′ may be formed on portions of the first gate insulating layer 630 and the second gate insulating layer 630′ under which the first gate electrode 620 and the second gate electrode 620′ are located. In accordance with one exemplary embodiment, a semiconductor oxide layer may be formed on the first gate insulating layer 630 and the second gate insulating layer 630′. Thereafter, the semiconductor oxide layer may be partially etched by a photolithography process or an etching process using an additional etching mask. Hence, the first active layer 640 and the second active layer 640′ may be provided on the first gate insulating layer 630 and the second gate insulating layer 630′. The semiconductor oxide layer may be formed by a sputtering process, a CVD process, a printing process, a spray process, a vacuum evaporation process, an ALD process, a sol-gel process, a PECVD process, etc. The first active layer 640 and the second active layer 640′ may include a binary compound containing indium, zinc, gallium, titanium, aluminum, halfnium, zirconium, magnesium, etc, a ternary compound, e.g., including such elements, and a quaternary compound, e.g., including such elements, etc. In one exemplary embodiment, the first active layer 640 and the second active layer 640′ may include, instead of or in addition to the above-listed compounds, a semiconductor oxide doped with lithium, sodium, manganese, nickel, palladium, copper, carbon, nitrogen, phosphorus, titanium, zirconium, vanadium, rubidium, germanium, tin, fluorine, etc. These may be used alone or in a mixture thereof.

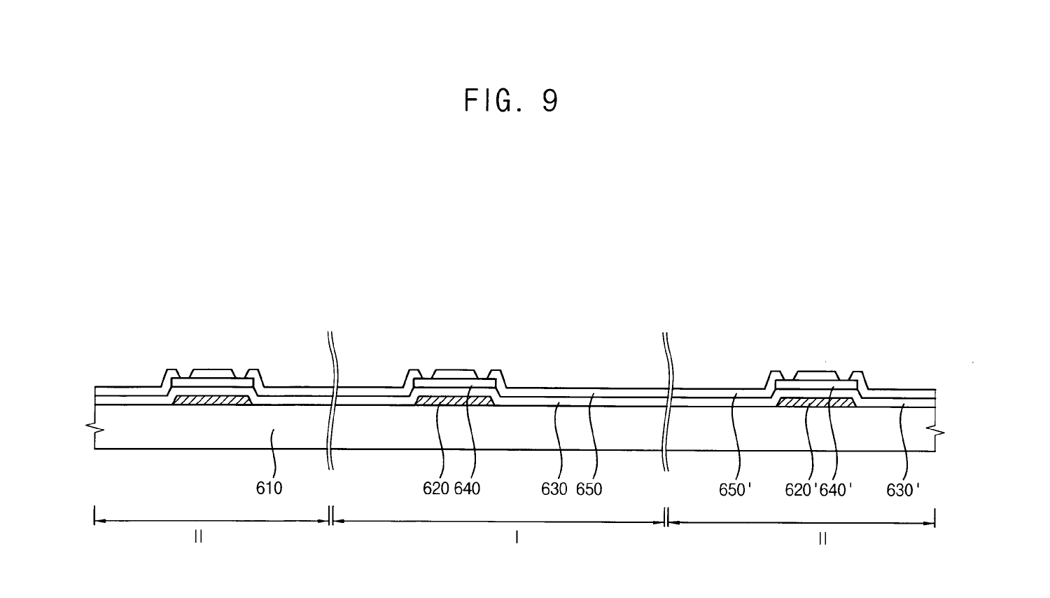

Referring to FIG. 9, a first insulating interlayer 650 and a second insulating interlayer 650′ may be disposed on the first gate insulating layer 630, the second gate insulating layer 630′, the first active layer 640, and the second active layer 640′ to cover the first gate insulating layer 630, the second gate insulating layer 630′, the first active layer 640, and the second active layer 640′.

In accordance with one exemplary embodiment, the first insulating interlayer 650 and the second insulating interlayer 650′ may be formed by a CVD process, a thermal oxidation process, a PECVD process, a HDP-CVD process, etc. The first insulating interlayer 650 and the second insulating interlayer 650′ may include silicon oxide, metal oxide, etc. For example, the first insulating interlayer 650 and the second insulating interlayer 650′ may include silicon oxide, silicon oxynitride, hafnium oxide, zirconium oxide, aluminum oxide, tantalum oxide, etc. These may be used alone or in a combination thereof.

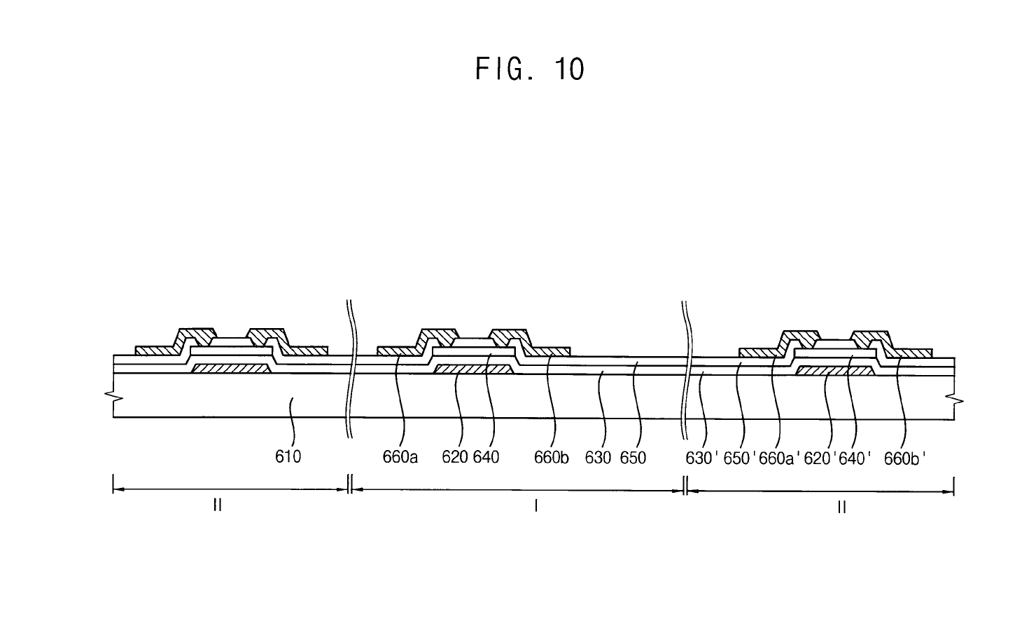

Referring to FIG. 10, contact holes may be formed through the first insulating interlayer 650 and the second insulating interlayer 650′. In accordance with one exemplary embodiment, a second conductive layer may be formed on the first gate insulating layer 630 and the second gate insulating layer 630′. Thereafter, the second conductive layer may be partially etched by a photolithography process or an etching process using an additional etching mask. Hence, the first source electrode 660a, the first drain electrode 660b, the second source electrode 660a′, and the second drain electrode 660b′ may be provided on the first insulating interlayer 650 and the second insulating interlayer 650′. The first source electrode 660a, the first drain electrode 660b, the second source electrode 660a′, and the second drain electrode 660b′ may include metal, alloy, conductive metal oxide, a transparent conductive material, etc. In accordance with one exemplary embodiment, the first source electrode 660a, the first drain electrode 660b, the second source electrode 660a′, and the second drain electrode 660b′ may have a single layer structure or a multi-layer structure, which may include a conductive material, a heat resistance material and/or a transparent conductive material.

A first electrode, an organic light emitting layer, a second electrode, etc. may be formed on the first source electrode 660a, the first drain electrode 660b, the second source electrode 660a′, and the second drain electrode 660b′ to manufacture the organic light emitting display device according to one exemplary embodiment.

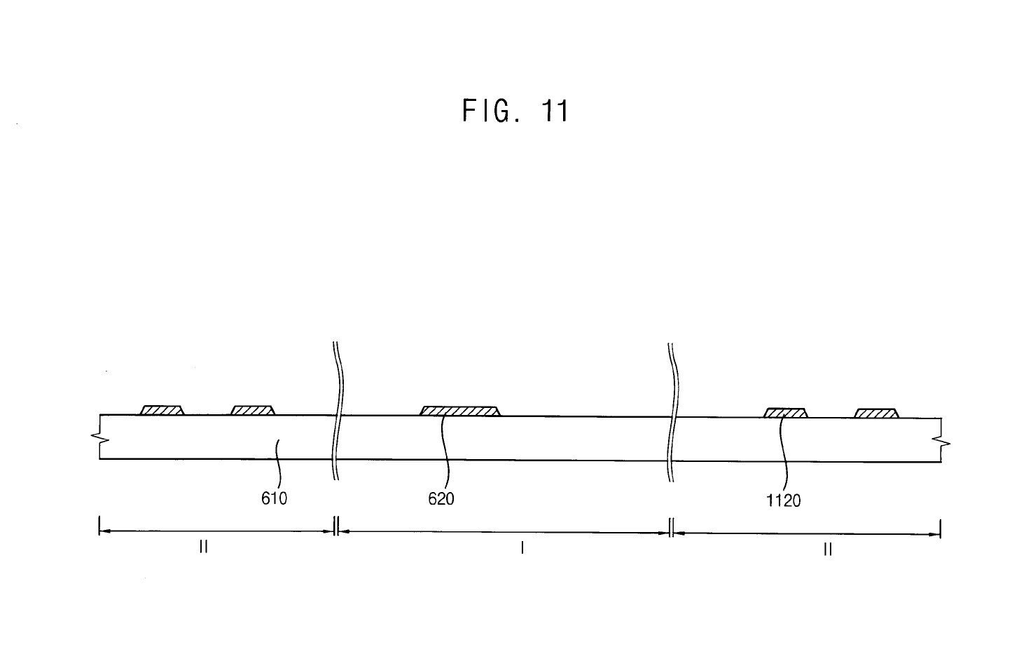

FIGS. 11 through 13 are diagrams illustrating a method of manufacturing an organic light emitting display device.

Referring to FIG. 11, a first gate electrode 620 and at least one first metal pattern 1120 may be formed on a substrate 610. In accordance with one exemplary embodiment, a first metal layer may be formed on the substrate 610. Thereafter, the first metal layer may be partially etched by a photolithography process or an etching process using an additional etching mask. Hence, the first gate electrode 620 and the first metal pattern 1120 may be provided on the substrate 610. The first conductive layer may be formed by a sputtering process, a CVD process, an ALD process, a vacuum evaporation process, a printing process, etc. The first gate electrode 620 and the first metal pattern 1120 may include a conductive material, a heat resistance material, and/or a transparent conductive material.

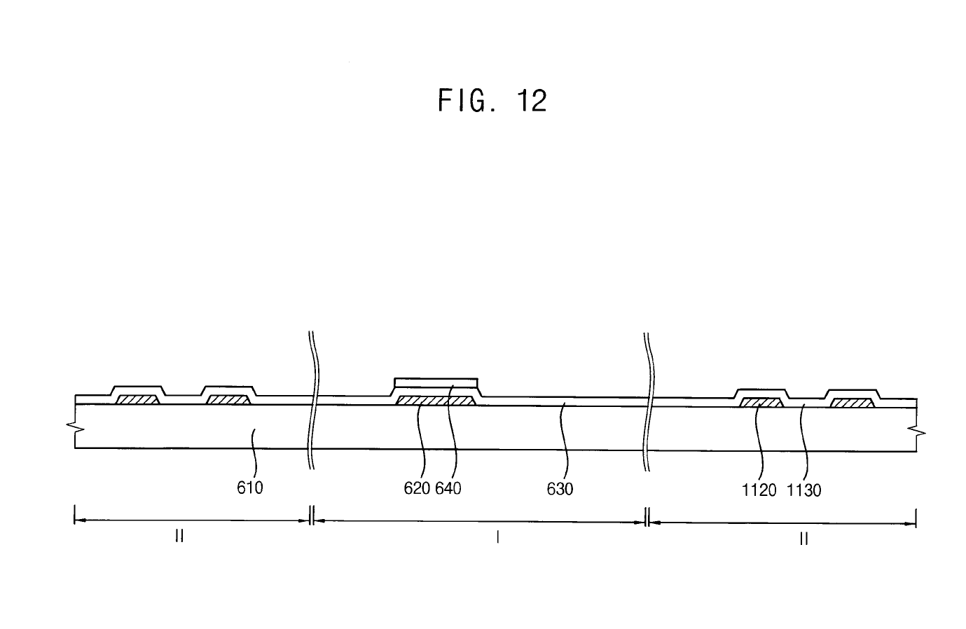

Referring to FIG. 12, a first active layer 640 and a second active layer 1130 may be formed on the first gate electrode 620 (or the first gate insulating layer 630) and the first metal pattern 1120. In accordance with one exemplary embodiment, a semiconductor oxide layer may be formed on the first gate electrode 620 (or the first gate insulating layer 630) and the first metal pattern 1120. Thereafter, the semiconductor oxide layer may be partially etched by a photolithography process or an etching process using an additional etching mask. Hence, the first active layer 640 and the second active layer 1130 may be provided on the first gate electrode 620 and the first metal pattern 1120. The semiconductor oxide layer may be formed by a sputtering process, a CVD process, a printing process, a spray process, a vacuum evaporation process, an ALD process, a sol-gel process, a PECVD process, etc. The first active layer 640 and the second active layer 1130 may include a binary compound containing indium, zinc, gallium, titanium, aluminum, halfnium, zirconium, magnesium, etc, a ternary compound, e.g., including such elements, and a quaternary compound, e.g., including such elements, etc. In one exemplary embodiment, the first active layer 640 and the second active layer 1130 may include a semiconductor oxide doped with lithium, sodium, manganese, nickel, palladium, copper, carbon, nitrogen, phosphorus, titanium, zirconium, vanadium, rubidium, germanium, tin, fluorine, etc. These may be used alone or in a mixture thereof.

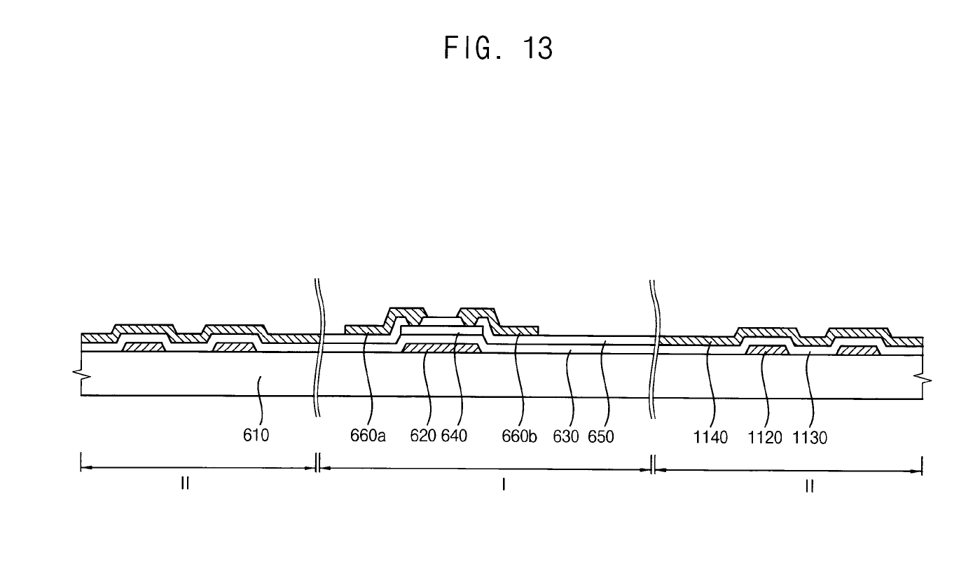

Referring to FIG. 13, a second metal layer may be formed on the semiconductor oxide layer. Thereafter, the second metal layer may be partially etched by a photolithography process or an etching process using an additional etching mask. Hence, the first source electrode 660a, the first drain electrode 660b, and the second metal pattern 1140 may be provided on the first active layer 640 and the second active layer 1130. The first source electrode 660a, the first drain electrode 660b, and the second metal pattern 1140 may include metal, alloy, conductive metal oxide, a transparent conductive material, etc. These may be used alone or in a mixture thereof.

A first electrode, an organic light emitting layer, a second electrode, etc. may be formed on the first active layer 640 and the second active layer 1130 to manufacture the organic light emitting display device according to one exemplary embodiment.

According to one exemplary embodiment of the invention, the organic light emitting display device may be used on an electronic device such as a mobile phone, a smart phone, a laptop computer, a tablet computer, a personal digital assistant (PDA), a portable multimedia player (PMP), a digital camera, a music player, a portable game console, a navigation device, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. An organic light emitting display device comprising:
a substrate comprising a display region and a plurality of peripheral regions adjacent the display region;
a display structure disposed in the display region; and
a strain gauge disposed in two peripheral regions facing each other among the plurality of peripheral regions.

2. The device of claim 1, wherein the display structure comprises:
a first gate electrode disposed on the substrate;
a first gate insulating layer disposed on the first gate electrode;
a first active layer disposed on the first gate insulating layer;
a first insulating interlayer overlying the first gate insulating layer and the first active layer;
a first source electrode connected to the first active layer;
a first drain electrode connected to the first active layer, and
wherein the display structure and the strain gauge structure are formed directly on the same layer.

3. The device of claim 2, wherein the strain gauge structure comprises:
a second gate electrode disposed on the substrate;
a second gate insulating layer disposed on the second gate electrode;
a second active layer disposed on the second gate insulating layer;
a second insulating interlayer overlying the second gate insulating layer and the second active layer;
a second source electrode connected to the second active layer;
a second drain electrode connected to the second active layer, and
wherein the plurality of peripheral regions surround the display region.

4. The device of claim 3, wherein the second active layer is configured to be electrically controllable based on a voltage that is applied to at least one of the second gate electrode, the second source electrode, and the second drain electrode.

5. The device of claim 4, wherein the second active layer comprises a semiconductor oxide, the semiconductor oxide comprising at least one of indium (In), zinc (Zn), gallium (Ga), tin (Sn), titanium (Ti), aluminum (Al), hafnium (Hf), zirconium (Zr), and magnesium (Mg).

6. The device of claim 1, wherein the strain gauge structure comprises:
at least one first metal pattern disposed on the substrate;
a third active layer disposed on the first metal pattern; and
a second metal pattern disposed on the third active layer, and
wherein the strain gauge structure and the display structure are formed directly on the same layer.

7. The device of claim 6, wherein the second metal pattern comprises an interdigitated structure.

8. The device of claim 7, wherein the third active layer is configured to be electrically controllable based on a voltage that is applied to at least one of the first metal pattern and the second metal pattern.

9. An organic light emitting display device comprising:
a substrate comprising a display region and a peripheral region adjacent the display region, the peripheral region having a plurality of peripheral regions;
a display structure disposed in the display region of the substrate; and
a strain gauge structure disposed in the entire plurality of peripheral regions.

10. The device of claim 9, wherein the display structure comprises:
a first gate electrode disposed on the substrate;
a first gate insulating layer disposed on the first gate electrode;
a first active layer disposed on the first gate insulating layer;
a first insulating interlayer overlying the first gate insulating layer and the first active layer;
a first source electrode connected to the first active layer;
a first drain electrode connected to the first active layer, and
wherein the display structure and the strain gauge structure are formed directly on the same layer.

11. The device of claim 9, wherein the strain gauge structure comprises:
a second gate electrode disposed on the substrate;
a second gate insulating layer disposed on the second gate electrode;
a second active layer disposed on the second gate insulating layer;
a second insulating interlayer overlying the second gate insulating layer and the second active layer;
a second source electrode connected to the second active layer;
a second drain electrode connected to the second active layer, and
wherein the strain gauge structure and the display structure are formed directly on the same layer.

12. The device of claim 11, wherein the second active layer is electrically controlled based on a voltage that is applied to at least one of the second gate electrode, the second source electrode, and the second drain electrode.

13. The device of claim 12, wherein the second active layer comprises a semiconductor oxide, the semiconductor oxide comprising at least one of indium, zinc, gallium, tin, titanium, aluminum, hafnium, zirconium, and magnesium.

14. The device of claim 9, wherein the strain gauge structure comprises:
at least one first metal pattern disposed on the substrate;
a third active layer disposed on the at least one first metal pattern;
a second metal pattern disposed on the third active layer, and
wherein the strain gauge structure and the display structure are formed directly on the same layer.

15. The device of claim 14, wherein the second metal pattern comprises an interdigitated structure.

16. The device of claim 15, wherein the third active layer is configured to be electrically controllable based on a voltage that is applied to at least one of the first metal pattern and the second metal pattern.

17. A method of manufacturing an organic light emitting display device, the method comprising:
forming a display structure in a display region of a substrate, the substrate comprising the display region and a plurality of peripheral regions adjacent the display region; and
forming a strain gauge in two peripheral regions facing each other among the plurality of peripheral regions.

18. The method of claim 17, wherein the display structure and the strain gauge structure are formed on the same layer of the substrate.

19. A method of manufacturing an organic light emitting display device, the method comprising:
forming a display structure in a display region of a substrate, the substrate comprising the display region and a plurality of peripheral regions adjacent the display region; and
forming a strain gauge in the entire plurality of peripheral regions.

20. The method of claim 19, wherein the display structure and the strain gauge structure are formed directly on the same layer.
